(19) United States
(12) Patent Application Publication
(10) Pub. No.: US 2013/0106632 A1
(43) Pub. Date: May 2, 2013

(54) CALIBRATION OF INTERLEAVED ADC

(71) Applicant: STMicroelectronics (Grenoble 2) SAS, Grenoble (FR)

(72) Inventors: Roger Petigny, Meylan (FR); Hugo Gicquel, Grenoble (FR); Fabien Reaute, Renage (FR)

(73) Assignee: STMICROELECTRONICS (GRENOBLE 2) SAS, Grenoble (FR)

(21) Appl. No.: 13/667,990

(22) Filed: Nov. 2, 2012

(30) Foreign Application Priority Data
Nov. 2, 2011 (FR) 1159924

(51) Int. Cl. H03M 1/10

(52) U.S. Cl. 341/120

(57) ABSTRACT

The disclosure is directed to an interleaved analog-to-digital converter having: first, second and third sub-converters; a control block configured to control the first sub-converter to sample a test signal and the second sub-converter to sample an input signal during a first sampling period, and to control the second sub-converter to sample the test signal and the third sub-converter to sample the input signal during a second sampling period.

### BACKGROUND

1. Technical Field

The present disclosure relates to an interleaved analog-to-digital converter (ADC) and to a method of performing an analog-to-digital conversion.

2. Description of the Related Art

FIG. 1 illustrates an example of an interleaved ADC comprising four sub-converters ADC1 to ADC4. Each of the sub-converters is coupled to an input line 102 via a corresponding switch 104 to 107 controlled by a respective timing signal φ1 to φ4 having respective phase offsets. Thus each of the sub-converters ADC1 to ADC4 samples an input signal Vin on the input line 102 at a different time, and provides a corresponding output signal D1 to D4 to respective inputs of a multiplexer (MUX) 108. Multiplexer 108 generates an output data signal Dout on a line 110 by periodically selecting each of the output signals D1 to D4 in turn.

Thus, by providing the four time-interleaved sub-converters ADC 1 to ADC4, the input signal Vin can be sampled at four times the rate of a single ADC, and thus the sampling frequency Fs can be four times as high.

In order to obtain a high quality digital output signal Dout, it would be desirable that the sub-converters ADC1 to ADC4 are well matched with each other, for example in terms of their respective voltage offsets and gains. However, these parameters may vary, for example due to PVT (process, voltage, temperature) variations, or other factors.

In order to correct such miss-matches, one option would be to provide a calibration phase for each sub-converter. However, a problem with such a solution is that it involves an interruption in the operation of the interleaved ADC or a reduction in its sampling frequency, either of which is undesirable due to the resulting reduction in performance/quality of the interleaved ADC.

There are also technical problems in calibrating the sub-converters to efficiently correct a miss-match without introducing further noise.

### BRIEF SUMMARY

According to one aspect, there is provided an interleaved analog-to-digital converter comprising: first, second and third sub-converters; a control block configured to control said first sub-converter to sample a test signal and said second sub-converter to sample an input signal during a first sampling period, and to control said second sub-converter to sample said test signal and said third sub-converter to sample said input signal during a second sampling period.

According to one embodiment, the control block comprises: a first synchronous delay element for generating a first sampling signal controlling said first sub-converter; a second synchronous delay element for generating a second sampling signal controlling said second sub-converter; and a third synchronous delay element for generating a third sampling signal controlling said third sub-converter; wherein said first, second and third synchronous delay elements are coupled in series.

According to another embodiment, the control block further comprises bypass circuitry for selectively coupling an output of said first synchronous delay element to an input of said third synchronous delay element, thereby bypassing said second synchronous delay element.

According to another embodiment, the bypass circuitry comprises a multiplexer comprising a first input coupled to the output of said first synchronous delay element, a second input coupled to the output of said second synchronous delay element, and an output coupled to the input of said third synchronous delay element.

According to another embodiment, each of said first, second and third sub-converters comprises a sampling capacitor and a switch controlled by the corresponding sampling signal to couple the sampling capacitor to a ground voltage.

According to another embodiment, the interleaved ADC further comprises a test signal generator arranged to generate said test signal.

According to another embodiment, the test signal generator comprises one of: a phase-locked loop; and a digital to analog converter. According to another embodiment, the interleaved ADC further comprises a first memory configured to store first test data generated by said first sub-converter, and a second memory configured to store second test data generated by said second or third sub-converters.

According to another embodiment, the interleaved ADC further comprises a calculation block coupled to said first and second memories, and arranged to compare said first and second test data and to generate a control signal based on said comparison.

According to another embodiment, the interleaved ADC further comprises calibration circuitry comprising a programmable delay.

According to a further aspect, there is provided an electronic device comprising the above interleaved ADC.

According to yet a further aspect, there is provided method of testing an interleaved ADC comprising first, second and third sub-converters, the method comprising: during a first sampling period, controlling by a control block said first sub-converter to sample a test signal and said second sub-converter to sample an input signal; and during a second sampling period, controlling by said control block said second sub-converter to sample said test signal and said third sub-converter to sample said input signal.

According to one embodiment, controlling the second sub-converter during said first sampling period comprises generating a sampling signal by bypassing a synchronous delay element.

According to yet a further aspect, there is provided a method of testing static skew in at least one sub-converter of an interleaved ADC, comprising the above method, wherein said test signal comprises a periodic signal generated by a test signal generator.

According to yet a further aspect, there is provided a method of measuring gain, voltage offset, skew and/or bandwidth in at least one sub-converter of an interleaved ADC, comprising the above method.

### BRIEF DESCRIPTION OF THE SEVERAL VIEWS OF THE DRAWINGS

The foregoing and other purposes, features, aspects and advantages of embodiments of the present disclosure will become apparent from the following detailed description of embodiments, given by way of illustration and not limitation with reference to the accompanying drawings, in which:

FIG. 1 illustrates an known example of an interleaved ADC;

FIG. 2 illustrates an interleaved ADC according to an example embodiment of the present disclosure;

FIG. 3 illustrates a control block of the interleaved ADC of FIG. 2 in more detail according to an example embodiment of the present disclosure;

FIG. 4 is a timing diagram illustrating timing pulses in the circuitry of FIG. 3 according to an example embodiment of the present disclosure;

FIG. 5 illustrates input circuitry of an ADC sub-converter of FIG. 2 in more detail according to an example embodiment of the present disclosure;

FIG. 6 illustrates an interleaved ADC according to a further example embodiment of the present disclosure;

FIG. 7A illustrates calibration circuitry according to an example embodiment of the present disclosure;

FIG. 7B illustrates calibration circuitry according to the further example embodiment of the present disclosure; and

FIG. 8 illustrates an electronic device according to an embodiment of the present disclosure.

### DETAILED DESCRIPTION

Throughout the following description, only those elements useful for an understanding of the various embodiments will be described in detail. Other aspects, such as the particular type and form of the analog to digital conversion circuitry, have not been described in detail, the following embodiments applying to a wide range of converter types, such as pipeline converters or SAR (successive approximation register) ADCs.

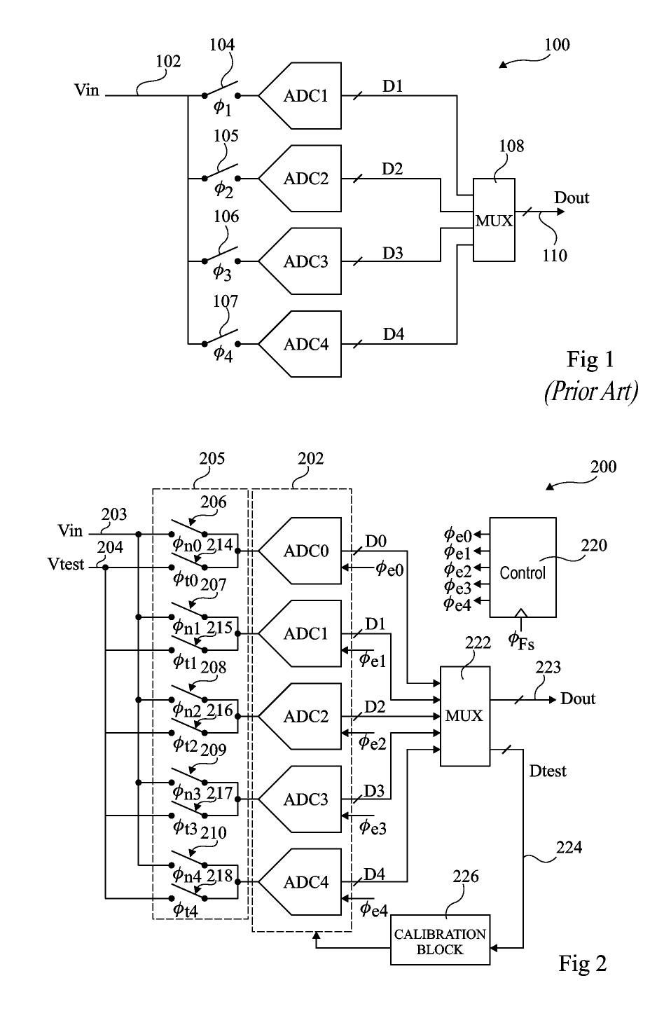

FIG. 2 illustrates an interleaved ADC 200 according to an example embodiment.

Interleaved ADC 200 has four sub-converters operating in parallel to sample an input signal Vin, but comprises a converter block 202 comprising five sub-converters ADC0 to ADC4. This hardware redundancy allows one of the sub-converters to be periodically taken off-line for testing, without disrupting the sampling sequence of the input signal.

The input of each sub-converter ADC0 to ADC4 is coupled to each of a pair of input lines 203 and 204 via a multiplexer 205. The input line 203 receives an analog input signal Vin to be converted, while the input line 204 receives an analog test signal Vtest to be applied to a sub-converter under test.

The multiplexer 205 comprises switches 206 to 210 coupling the sub-converters ADC0 to ADC4 respectively to the input line 203, and switches 214 to 218 coupling the sub-converters ADC0 to ADC4 respectively to the input line 204. Switches 206 to 210 are controlled by timing signals φₙ₀ to φₙ₄, while the switches 214 to 218 are controlled by timing signals φₜ₀ to φₜ₄. Each of the sub-converters ADC0 to ADC4 also receives a timing signal φₑ₀ to φₑ₄, which controls the sampling time of each sub-converter. These signals are generated by a control block 220, based on a clock signal φ_{Fs}, which is for example a clock signal at the sampling frequency Fs.

Outputs D0 to D4 of the sub-converters ADC0 to ADC4 are supplied to corresponding inputs of a multiplexer (MUX) 222, which selects certain outputs in turn to form an output data signal Dout on an output line 223. The multiplexer 222 also provides a test output signal Dtest on lines 224 to a calibration block (CALIBRATION BLOCK) 226. Signal Dtest corresponds to the output of the sub-converter that is being tested at a given time. The calibration block 226 generates a control signal in response to the test output signal, which is used to calibrate one or more of the sub-converters ADC0 to ADC4 of block 202, as will be described in more detail below.

The test signal Vtest on line 204 and the resulting test data Dtest provided to the calibration block 226 for example allow one or more of an offset voltage, gain, static skew and bandwidth measurement to be made. The calibration block 226 is adapted to make the appropriate correction to the corresponding sub-converter, as will be described in more detail below.

The number of bits forming each output signal D0 to D4 and each of the output data signals Dout and Dtest will depend on the size of the sub-converters ADC0 to ADC4, and could be any number equal to or greater than 2.

Of course, while FIG. 2 illustrates the example of five sub-converters, more generally there could be N+M sub-converters, where N is the number of sub-converters operating in parallel at any one time, in other words N is the number of times the input signal is sampled during the conversion cycle of one converter. For example, N could be any number equal to or greater than 2. M is the number of additional sub-converters, which could be equal to 1, or in some embodiments could be greater than 1, if for example it is desired to provide some back-up converters to be used if one of the sub-converters becomes non-operational.

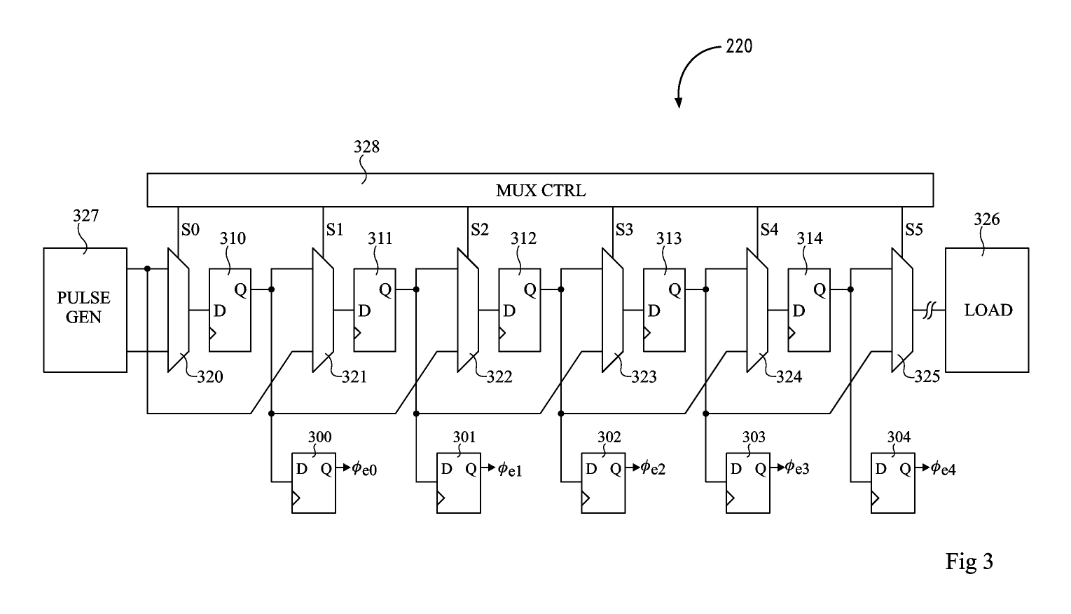

FIG. 3 illustrates the control block 220 of FIG. 2 in more detail according to one embodiment.

As illustrated, the timing signals φₑ₀ to φₑ₄ are provided at outputs of five corresponding D-type flip-flops 300 to 304 respectively. Each of these flip-flops 300 to 304 receives at its data input the Q output of a respective D-type flip-flop 310 to 314. Five two-input multiplexers 320 to 324 have their outputs coupled to the data inputs of flip-flops 310 to 314 respectively. Multiplexer 320 is optional, and performs the role of providing balance to the input side of the circuit, such that the input node of D-type flip-flop 310 has similar characteristics to the other flip-flops 311 to 314. A further two-input multiplexer 325 is also optional, and for example has its output coupled to a load block (LOAD) 326 and its first and second inputs coupled to the Q output of D-type flip-flops 313 and 314 respectively. Load block 326 for example has input characteristics similar to those of a D-type flip-flop. Thus the multiplexer 325 and load block 326 perform the role of balancing the circuit such that the output nodes of D-type flip-flops 313 and 314 have similar characteristics to the output nodes of the other flip-flops 310 to 312. Both inputs of multiplexer 320 are coupled to respective outputs of a pulse generation block (PULSE GEN) 327. First inputs of multiplexers 321 to 324 are respectively coupled to the Q outputs of flip-flops 310 to 313. The second input of multiplexer 321 is coupled to the same output of the pulse generation block 327 as the first input of multiplexer 320. The second inputs of multiplexers 322 to 324 are coupled to the Q outputs of flip-flops 310 to 312 respectively. The multiplexers 320 to 325 are controlled by control signals S0 to S5 respectively, which are provided by a multiplexer control block (MUX CTRL) 328.

Each of the D-type flip-flops 300 to 304 and 310 to 314 is for example timed by the clock signal φ_{Fs} (not illustrated in FIG. 3).

The implementation of the control block 220 of FIG. 3 is adapted to the example of five sub-converters, but of course it will be apparent to those skilled in the art that this circuitry could be scaled for a different number of sub-converters, by adding flip-flops and multiplexers between multiplexer 325 and load 326, or by removing one or more of the multiplexers and flip-flops.

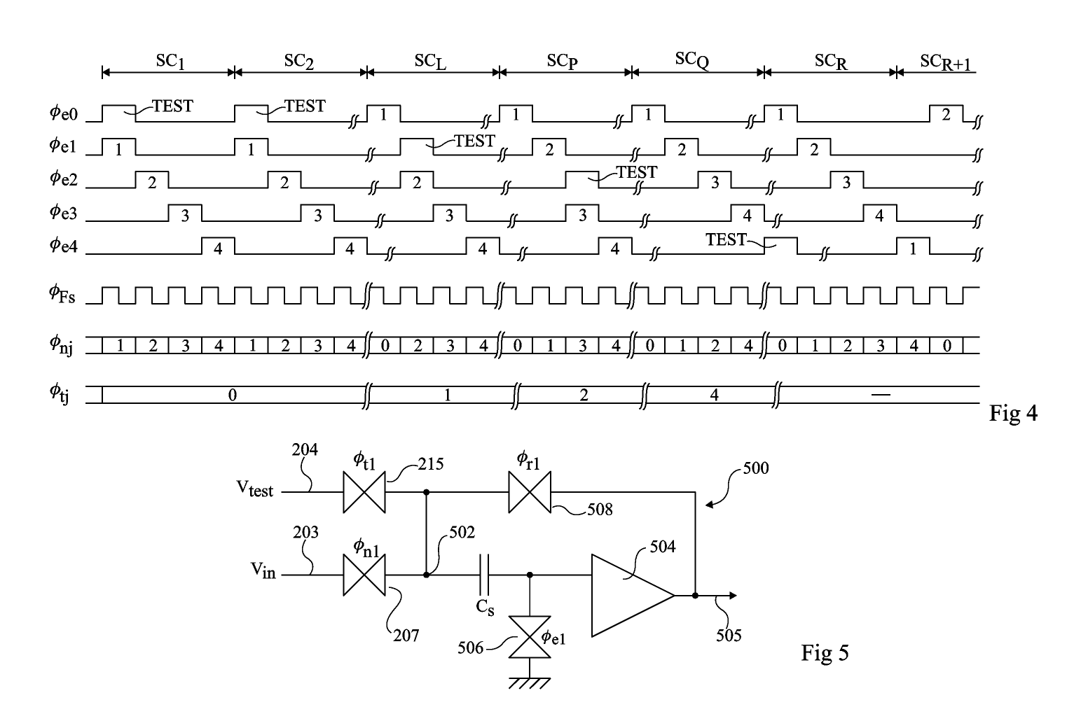

Operation of the circuit of FIG. 3 will now be described with reference to the timing diagram of FIG. 4.

FIG. 4 illustrates the example of the timing signals φₑ₀ to φₑ₄ and φ_{Fs}, and the corresponding switch control signals φₙ₀ to φₙ₄ and φₜ₀ to φₜ₄, which are shown grouped together on rows labelled φₙⱼ and φₜⱼ in FIG. 4.

In the example of FIG. 4, the sub-converters ADC0 to ADC4 of FIG. 2 are each tested in turn over a number of sampling cycles. The pulse generator block 327 generates a pulse on its first output to trigger each sampling cycle.

During a first sampling cycle SC₁, the sub-converter ADC0 is tested, and sub-converters ADC1 to ADC4 perform sampling of the input signal Vin. Thus, during cycle SC₁, the signal φₜ₀ is high. During the first sampling cycle, multiplexers 320 and 322 to 325 are controlled by control signals S0 and S2 to S5 respectively to select their first inputs, while multiplexer 321 is controlled to select its second input, coupled to the output of pulse generator block 327. Thus, pulse generator block 327 generates a pulse to trigger the first sampling cycle SC₁, and two periods of the clock signal φ_{Fs} later, the control signals φₑ₀ and φₑ₁ will have high pulses occurring at the same time. The pulse of sampling signal φₑ₀ is a test pulse controlling sub-converter ADC0 to sample the test signal Vtest. The pulse of sampling signal φₑ₁ is a first sampling period “1” of the input signal Vin during the sampling cycle SC₁, and thus signal φₙ₁ is high.

Although not shown in FIG. 4, at the same time as sampling signals φₑ₀ and φₑ₁ go high, the signal at the output of flip-flop 312 will go high. Thus, on the subsequent rising edge of the clock signal φ_{Fs}, the sampling signal φₑ₂ at the output of flip-flop 302 will go high, which is labelled as a sampling period “2” of the sampling cycle SC₁, and the signal φₙ₂ is high. The output of flip-flop 313 will also go high, such that on the subsequent rising edge of clock signal φ_{Fs}, the sampling signal φₑ₃ at the output of flip-flop 303 will go high, which is labelled as a sampling period “3” of the sampling cycle SC₁, and signal φₙ₃ is high. The output of flip-flop 314 will also go high, and thus on the subsequent rising edge of clock signal φ_{Fs}, the sampling signal φₑ₄ at the output of flip-flop 304 will go high, which is labelled as a sampling period “4” of the sampling cycle SC₁, and the signal φₙ₄ is high. This completes the sampling cycle SC₁.

During the subsequent sampling cycle SC₂, the sub-converter ADC0 is again tested, and thus the sequence of pulses of the signals φₑ₀ to φₑ₄ is the same as for sampling cycle SC₁. As indicated by interruption signs in FIG. 4, following the sampling cycle SC₂, there may be any number of additional sampling cycles in which the sub-converter ADC0 is tested. More generally, each converter may be tested over one or more sampling cycles.

The next sampling cycle illustrated in FIG. 4, which is the Lth sampling cycle, where L depends on the number of cycles during which the sub-converter ADC0 was tested. During the Lth sampling cycle, the sub-converter ADC1 is tested, and thus the signal φₜ₁ is high. Furthermore, multiplexers 320, 321 and 323 to 325 are controlled by control signals S0, S1 and S3 to S5 respectively to select their first inputs, while multiplexer 322 is controlled to select its second input, coupled to the output of D-type flip-flop 310. Thus, the control signals φₑ₁ and φₑ₂ have high pulses at the same time. The pulse of sampling signal φₑ₁ is a test pulse controlling sub-converter ADC1 to sample the test signal Vtest. Thus signal φₜ₁ is also high. The pulse of sampling signal φₑ₂ is a sampling period “2” of the sampling cycle SC_{L}, and thus signal φₙ₂ is high. On subsequent rising edges of the sampling signal φ_{Fs}, sampling periods “3” and “4” of the sampling cycle SC_{L} are provided by sampling signals φₑ₃ and φₑ₄, completing the sampling cycle SC_{L}.

As indicated by interruptions in FIG. 4, there may be one or more further sampling cycles in which sub-converter ADC2 is tested.

The remaining sub-converters ADC2 to ADC4 are then tested in a similar fashion by bypassing these sub-converters during the corresponding cycles and using the subsequent sub-converter in the sequence to perform the sampling operation of the input signal Vin. In particular, in the next sampling cycle SC_{Q} shown in FIG. 4, the sub-converter ADC2 is tested for one or more sampling cycles. For the sake of brevity, the subsequent testing of sub-converter ADC3 is not illustrated in FIG. 4. Then, during a Qth sampling cycle SC_{Q} shown in FIG. 4, the last sub-converter ADC4 is tested, and this test may continue for one or more sampling cycles, thereby completing the testing of the five sub-converters ADC0 to ADC4.

After each of the sub-converters has been tested, sampling of the input signal Vin may continue using all of the sub-converters, with each of the multiplexers 320 to 325 being controlled to select its first input. Thus, as illustrated in FIG. 4 by sampling cycle SC_{R}, the sampling periods “1” to “4” during this sampling cycles are performed by sub-converters ADC0 to ADC3 respectively, and as illustrated by the subsequent sampling cycle SC_{R+1}, the sampling periods “1” and “2” of the next sampling cycle are performed by sub-converters ADC4 and ADC0 respectively. An advantage of this sequence is that it is simple to implement and calibration of the sub-converters may be recommenced at any moment, with out altering the operating speed of any of the sub-converters.

FIG. 5 illustrates an example of input circuitry 500 of the sub-converter ADC1 along with the input switches 215 and 207. The other sub-converters ADC0 and ADC2 to ADC4 may comprise identical circuitry.

As shown in FIG. 5, the switches 215 and 207 are coupled into an input node 502, which is in turn coupled to the input of an operational amplifier 504, via a sampling capacitor C_{S}. The input of amplifier 504 is also coupled to ground via a sampling switch 506, which controls the sampling of the sub-converter, under the control of the sampling signal φₑ₁. The output of amplifier 504 on line 505 is for example provided to further conversion circuitry of the ADC (not shown in FIG. 5) for performing the analog to digital conversion. The output is also fed back to the input node 502 via a switch 508.

The sub-converter ADC1 has two main modes of operation: a sampling phase and a conversion phase.

During the sampling phase, the signal φₑ₁ is asserted, along with one or the other of the signals φₜ₁ and φₙ₁, depending on whether the sub-converter is to sample the input signal Vin or the test signal Vtest. During this sampling phase, switch 508 of the feedback path is non-conducting.

During the conversion phase, the input node 502 is isolated from the input lines 203 and 204 by deactivating switches 215 and 207. The sampling switch 506 is also non-conducting, and the feedback path 508 is connected, by activating transistor 508. Thus the output of the amplifier 504 matches the voltage stored on the sampling capacitor C_{S}, and is used to drive the subsequent conversion circuitry of the sub-converter ADC1. As indicated above, this conversion circuitry could be of a variety of types, such as a SAR (successive approximation register) or pipelined ADC.

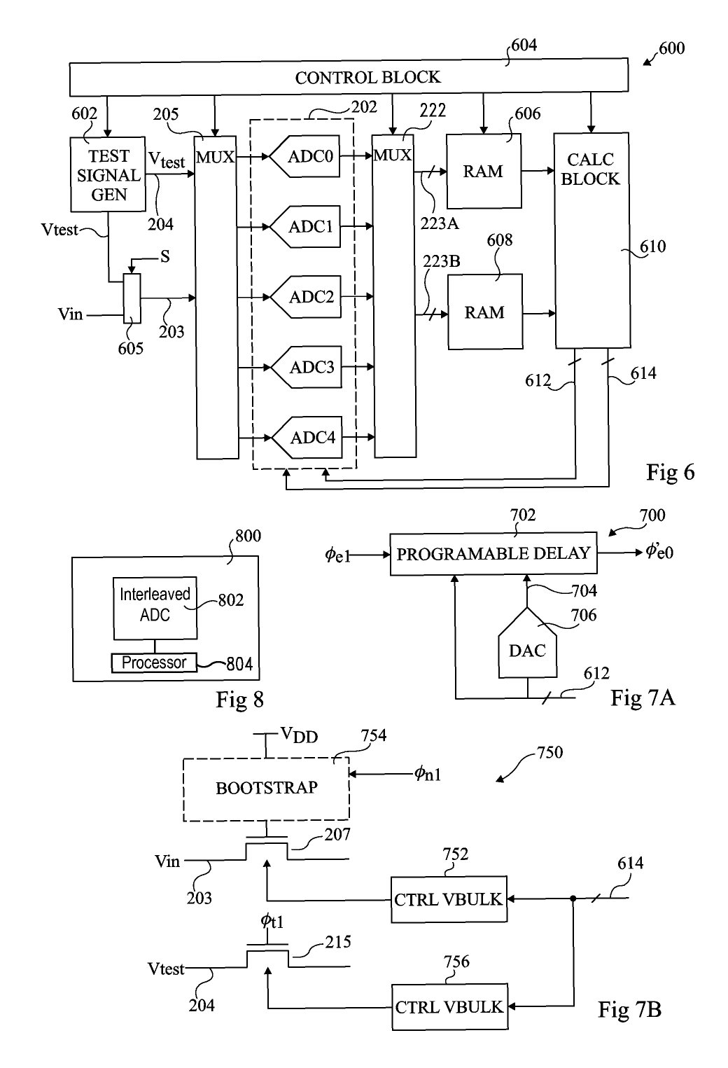

FIG. 6 illustrates an interleaved ADC 600 according to a further embodiment. Those elements identical to elements of FIG. 2 have been labelled with like reference numerals, and will not be described again in detail.

Interleaved ADC 600 comprises the sub-converter block 202 and the multiplexers 205 and 222 (MUX) of FIG. 2. The test signal Vtest on line 204 is provided by a test signal generator (TEST SIGNAL GEN) 602, which is controlled by a control block (CONTROL BLOCK) 604. Test signal generator 602 also provides a test signal Vtest to one input of a switching block 605, which receives at a second input the input signal Vin, and has its output coupled to the line 203. Generator 602 is for example synchronous, and may be implemented by a phase-locked loop. Alternatively, generator 602 could be implemented by a digital to analog converter, for example with an output filter.

The test output lines 223 of multiplexer 220 of FIG. 2 comprise, in the example of FIG. 6, an output 223A coupled to a RAM (random access memory) 606, and an output 223B coupled to a RAM 608, although other types of memories could be used. RAMs 606 and 608 have outputs coupled to a calculation block (CALC BLOCK) 610, which for example provides two digital control signals on control lines 612 and 614 respectively to the sub-converter block 202.

In operation, one of the sub-converters ADC0 to ADC4 is for example selected as a golden converter, in other words as a reference to which the other sub-converters are matched. For example, ADC0 performs this role. Thus, ADC0 is for example the first ADC to be tested by the test signal Vtest, and the test data resulting from this test are stored in the RAM 606. When each of the other sub-converters ADC 1 to ADC4 is tested, the corresponding results are stored in RAM 608, and compared to the results stored in memory 606 by the calculation block 610 in order to generate the control signals on lines 612 and/or 614.

The test signal Vtest is for example a periodic signal, which could have the form of a sinusoid, or other forms such as a triangular or sawtooth wave.

The test signal generator 602 of FIG. 6 for example allows static skew and/or bandwidth measurements to be made in each of the sub-converters ADC0 to ADC4.

For testing static skew, the test signal Vtest is for example provided to the sub-converter under test via the line 204.

The bandwidth of each sub-converter results, at least to some extent, from the resistive and capacitive elements of the switches of multiplexer 205. Given that bandwidth variations may affect the skew measurements, the bandwidth of the test path via line 204 is for example tested for each sub-converter ADC0 to ADC4. However, for measuring bandwidth of the path of the input signal Vin, the test signal is for example provided to the sub-converter under test via the line 203, i.e., via the switch 207 of FIG. 4 that is used for receiving the actual signal Vin to be converted. The switching block 605 is controlled by a control signal S to connect the test signal Vtest to the line 203 when the bandwidth test is to be performed. The switching block 605 is for example configured to have a low impedance output that is independent of the input that is selected. For example, the switching block 605 comprises an amplifier. Of course, during this test period the interleaved ADC is for example in a calibration mode during which it does not convert the input signal Vin.

To test bandwidth, some relatively high frequencies fₜₑₛₜ of the test signal Vtest are for example generated by the test signal generator 602, and attenuation of the signal by each sub-converter under test for a range of said frequencies is for example compared to the attenuation of the signal resulting from the same test signal applied to the reference sub-converter ADC0.

Static skew results from a difference in the time delay of the sampling signal provided to each sub-converter. In one example, the static skew is estimated and corrected as follows using a sinusoidal test signal.

After applying a sinusoidal test signal Vtest to the reference sub-converter, and processing the resulting test data Dtest to extract any offset, the reference signal x(t) can be assumed to have the following equation:

x(t)=a₀*sin(2*π*f*t)

where a₀ is the gain of the reference sub-converter, which is sub-converter ADC0 in this example, f is the frequency of the sinusoid test signal, and t is the time of the sample. The number of samples of the test signal will depend on the factors such as the noise in the system, and could be several thousand or more.

Then, using a similar process for the sub-converter ADCn to be tested, the output data can be assumed to have the following equation:

yₙ(t)=aₙ*sin(2*π*f*(t+n*Tₑ+δtₙ))

where aₙ is the gain of the sub-converter n, f is the frequency of the sinusoid test signal, t is the time of the sample, Tₑ is the ideal time delay between sampling periods, i.e., the period of the clock signal φ_{Fs}, and δtₙ is the time skew of sub-converter ADCn with respect to the reference converter ADC0. The number of samples of the test signal taken by each of the sub-converters ADCn is for example the same as the number used to test the reference converter ADC0.

The multiplication of signals x(t) by y(t) will result in a signal comprising the sum of frequencies and difference of frequencies of these signals. Thus, based on the mean z=mean(x*y/a₀*aₙ) of this sum for a whole number of periods, the value of δtₙ can be determined as follows:

δtₙ=1/(2*π*f)*arccos(2*z)−nTₑ

This test is for example preformed for a relatively low frequency test signal, for example in a frequency range of 300 to 400 MHz, and then repeated for a relatively high frequency test signal, for example in a frequency range of 1 GHz or more.

Examples of calibration circuitry of the sub-converter ADC1 will now be described with reference to FIGS. 7A and 7B. Similar circuitry could be provided in the other sub-converters ADC0 and ADC2 to ADC4.

FIG. 7A illustrates an example of calibration circuitry 700 of the sub-converter ADC1 for adjusting the sampling time of signal φₑ₁ provided to the switch 506 of FIG. 5 based on the control signal from the calculation block 610 of FIG. 6. This allows a skew mismatch to be corrected. In particular, a programmable delay (PROGRAMABLE DELAY) 702 is coupled in the path of the sampling signal φₑ₁, which allows a delay to be selected, for example by coupling one or more inverters into the delay path. The selection is performed via one or both of digital and analog control signals. The digital control signal is for example provided directly by the digital control lines 612 from the calculation block 610, while the analog control signal is provided by a digital to analog converter (DAC) 706, which converts the digital signal on line 612 to an analog control signal. For example, the digital control signal provides a rough control of the delay, and the analog control signal provides fine control of the delay.

FIG. 7B illustrates a further example of calibration circuitry 750 of the sub-converter ADC1 according to a further example, which may be included as an alternative or in addition to the circuitry 700. The circuitry 750 provides bandwidth compensation, for example to both the path of the input voltage Vin, and also the path of the test signal Vtest.

As mentioned above, the bandwidth of each sub-converter ADC0 to ADC4 is determined to at least some extent by the resistive and capacitive elements of the input circuitry 500, which effectively result in an RC filter. Bandwidth compensation is for example applied to the input circuitry of the input signal Vin using a control block (CTRL VBULK) 752, which controls the bulk voltage Vbulk of the input transistor 207 of ADC1 based on the digital control signal on lines 612 from the calculation block 610 of FIG. 6. Thus the control block 752 for example comprises a digital to analog converter, and/or other circuitry for generating the analog voltage level to be applied the bulk node of transistor 207. Transistor 207 is coupled between the input line 203 supplying the input signal Vin and the input circuitry 500 of FIG. 5. By varying its bulk voltage, its on resistance Ron may also be varied, leading to a modification of the pass band of the converter.

The gate node of transistor 207 is for example controlled by an optional bootstrap circuit (BOOTSTRAP) 754 coupled between the gate node and the supply voltage V_{DD}. The bootstrap circuit is activated by the control signal φₙ₁ to apply a gate voltage to the gate node of transistor 207.

In a similar fashion, bandwidth compensation may be applied to the input circuitry of the test signal Vtest using a control block (CTRL VBULK) 756, which controls the bulk voltage Vbulk of the input transistor 215 of ADC1 based on the digital control signal on lines 612 from the calculation block 610 of FIG. 6. Thus the control block 756 for example comprises a digital to analog converter, and/or other circuitry for generating the analog voltage level to be applied the bulk node of transistor 215. Transistor 215 is coupled between the input line 204 supplying the test signal Vtest and the input circuitry 500 of FIG. 5. By varying its bulk voltage, its on resistance Ron may also be varied, leading to a modification of the pass band of test circuitry of the converter. While not shown in FIG. 7B, the gate node of transistor 215 may be controlled by a bootstrap circuit in a similar fashion to transistor 207.

FIG. 8 illustrates an electronic device 800 comprising an interleaved ADC 802, which is for example the ADC 200 of FIG. 2 or the ADC 600 of FIG. 6. The electronic device 800 is for example a portable device such as a mobile phone, laptop computer, digital camera, portable games console or the like, or other type of electronic device that includes processing circuitry 804.

An advantage of modifying the bulk voltage of the input switch of a sub-converter of the interleaved ADC is that the bandwidth of the sub-converter can be modified, thereby leading to an improved matching between the sub-converters. Furthermore, this calibration method and circuit may be implemented in a simple fashion, without adversely affecting other parameters of the sub-converter, such as static skew.

An advantage of the embodiments described herein for controlling the sampling of the sub-converters is that one or more sub-converters may be bypassed in order to allow it to be tested, without risk of altering the characteristics of the sampling signal when it is routed to a different converter. Furthermore, the interleaved ADC may continue to operate normally during the test of each sub-converter, without a reduction in performance.

Having thus described at least one illustrative embodiment of the disclosure, various alterations, modifications and improvements will readily occur to those skilled in the art.

For example, it will be appreciated by those skilled in the art that numerous variations may be applied to the circuits described in relation to the various embodiments.

For example, while the various switches are represented as MOS transistor, other transistor technology may be used. Furthermore, it will be apparent to those skilled in the art that the flip-flops 300 to 304 of FIG. 3 could be omitted, the sampling signals φₑ₀ to φₑ₄ being provided directly by the outputs of flip-flops 310 to 314.

Furthermore, it will be apparent to those skilled in the art that the memories 606 and 608 of FIG. 6 could be implemented by separate memory devices such as random access memories (RAMs), or by a single RAM. Furthermore, it will be apparent to those skilled in the art that the features described in relation to the various embodiments may, in alternative embodiments, be combined in any combination, and that the functional blocks of the various embodiments could be implemented in hardware, software or any combination thereof.

Such alterations, modifications, and improvements are intended to be part of this disclosure, and are intended to be within the spirit and the scope of the present disclosure. Accordingly, the foregoing description is by way of example only and is not intended to be limiting.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An interleaved analog-to-digital converter (ADC), comprising:
first, second, and third ADC sub-converters; and
a control block configured to control said first sub-converter to sample a test signal and said second sub-converter to sample an input signal during a first sampling period, and to control said second sub-converter to sample said test signal and said third sub-converter to sample said input signal during a second sampling period, the control block including:
a first synchronous delay element coupled to the first sub-converter;
a second synchronous delay element coupled to the second sub-converter;
a third synchronous delay element coupled to the third sub-converter; and
bypass circuitry configured to selectively couple an output of the first synchronous delay element to an input of the third synchronous delay element, to bypass the second synchronous delay element.

2. The interleaved ADC of claim 1, wherein:
the first synchronous delay element is configured to generate a first sampling signal and is configured to control said first sub-converter using the first sampling signal;
the second synchronous delay element is configured to generate a second sampling signal and is configured to control said second sub-converter using the second sampling signal; and
the third synchronous delay element is configured to generate a third sampling signal and is configured control said third sub-converter using the third sampling signal wherein said first, second and third synchronous delay elements are coupled in series.

3. (canceled)

4. The interleaved ADC of claim 1, wherein said bypass circuitry comprises a multiplexer including a first input coupled to the output of said first synchronous delay element, a second input coupled to an output of said second synchronous delay element, and an output coupled to the input of said third synchronous delay element.

5. The interleaved ADC of claim 2, wherein each of said first, second and third sub-converters includes a sampling capacitor and a switch configured to be controlled by the corresponding sampling signal and configured to couple the sampling capacitor to a ground voltage.

6. The interleaved ADC of claim 1, further comprising a test signal generator arranged to generate said test signal.

7. The interleaved ADC of claim 6, wherein said test signal generator comprises one of:
a phase-locked loop; and
a digital to analog converter.

8. The interleaved ADC of claim 1, wherein the first sub-converter is configured to generate first test data and the second and third sub-converters are configured to generate second test data, the interleaved ADC further comprising a first memory configured to store the first test data, and a second memory configured to store the second test data.

9. The interleaved ADC of claim 8, further comprising a calculation block coupled to said first and second memories, and arranged to compare said first and second test data and to control at least one of the sub-converters based on said comparison.

10. The interleaved ADC of claim 1, further comprising:
a multiplexer having inputs respectively coupled to outputs of the first, second, and third sub-converters, the multiplexer being configured to generate on an output of the multiplexer a test output signal based on sampled outputs from the sub-converters; and
calibration circuitry configured to calibrate at least one of the sub-converters based on the test output signal.

11. An electronic device, comprising:
processing circuitry; and
an interleaved analog-to-digital converter (ADC) coupled to the processing circuitry, the ADC including:
first, second, and ADC third sub-converters; and
a control block configured to control said first sub-converter to sample a test signal and said second sub-converter to sample an input signal during a first sampling period, and to control said second sub-converter to sample said test signal and said third sub-converter to sample said input signal during a second sampling period, the control block including:
a first synchronous delay element coupled to the first sub-converter;
a second synchronous delay element coupled to the second sub-converter;
a third synchronous delay element coupled to the third sub-converter; and
bypass circuitry configured to selectively couple an output of the first synchronous delay element to an input of the third synchronous delay element, to bypass the second synchronous delay element.

12. The device of claim 11, wherein:
the first synchronous delay element is configured to generate a first sampling signal and is configured to control said first sub-converter using the first sampling signal;
the second synchronous delay element is configured to generate a second sampling signal and is configured control said second sub-converter using the second sampling signal; and
the third synchronous delay element is configured to generate a third sampling signal and is configured control said third sub-converter using the third sampling signal wherein said first, second and third synchronous delay elements are coupled in series.

13. (canceled)

14. The device of claim 11, wherein said bypass circuitry comprises a multiplexer including a first input coupled to the output of said first synchronous delay element, a second input coupled to an output of said second synchronous delay element, and an output coupled to the input of said third synchronous delay element.

15. A method of testing an interleaved analog-to-digital converter (ADC), comprising:
sampling signals with first, second, and third ADC sub-converters of the interleaved ADC by providing control signals from a control block to the first, second, and third ADC sub-converters, the sampling including:
during a first sampling period, sampling a test signal with the first sub-converter and sampling an input signal with the second sub-converter; and
during a second sampling period, sampling the test signal with the second sub-converter and sampling the input signal with the third sub-converter.

16. The method of claim 15, wherein controlling said second sub-converter during said first sampling period includes generating a sampling signal by bypassing a synchronous delay element.

17. The method of claim 15, further comprising:
testing static skew in one of the sub-converters by generating the test signal in a test signal generator to have a periodic signal.

18. The method of claim 4, further comprising:
measuring gain, voltage offset, skew, or bandwidth in one of the sub-converters.
